(19) United States
(12) Patent Application Publication
(10) Pub. No.: US 2004/0023454 A1
(43) Pub. Date: Feb. 5, 2004

(54) Method for utilizing re-oxidation of nitride layer to form super thin nitride gate oxide layer

(76) Inventors: June-Min Yao, Hsinchu (TW); Shu-Ya Hsu, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/211,286

(22) Filed: Aug. 5, 2002

(51) Int. Cl. H01L 21/8238; H01L 21/336; H01L 21/31

(52) U.S. Cl. 438/216; 438/287; 438/769; 438/770

(57) ABSTRACT

The present invention generally relates to provides a method for utilizing a re-oxidation step of a nitride layer to form a super thin nitride gate oxide layer. First, an oxide layer or a nitride oxide layer provided with a high nitrogen contain and a very thin thickness is growing on a semiconductor substrate, wherein the oxide layer can be provided with a large quantity nitrogen element by a nitrogen-penetrating treatment. Then, a second oxide layer is growing by a rapidly thermal step. Since in the second time to perform the oxidation of the substrate, the oxygen atom must penetrate the nitrogenized oxide layer to perform the oxidation with the substrate, so the present invention can decrease the oxidation rate and obtain a dense gate oxide layer with a good interface performance. The present invention can improve the disadvantage of too fast oxidation rate of the super thin gate oxide layer process and overcome the disadvantage of the difficult for obtaining a uniform and dense oxide layer.

### BACKGROUND OF THE INVENTION

1. Field of the Invention

The present invention generally relates to a semiconductor device manufacture process, and more particularly relates to a method for forming super thin nitride gate oxide layer, wherein the method can prevent the too fast oxidation rate so as to enhance the uniform and dense ability of the oxide layer and to make the thickness control more accurately.

2. Description of the Prior Art

Accordingly, no matter manufacturing simple semiconductor devices or complicated integrated circuits, the membrane is the most essential element of the device in the manufacturing process. In generally, the membrane used in the semiconductor manufacturing process is basically distinguished into four categories, including the thermal oxide layer, the dielectric layer, the polysilicon layer, and the metal layer. Wherein the basic function of the thermal oxide layer formed by thermal oxidation is used as a gate oxide layer and field oxide layer.

The principle of the thermal oxidation is to expose a semiconductor substrate in a oxygen-contain surrounding and then the semiconductor atom on the wafer surface will react with the oxygen to form the oxide layer which is so-called oxidation reaction. Take the common semiconductor substrate, such as silicon wafer, for an example, there are two kinds of the oxidation reaction, one is to react with oxygen, and another is to react with water molecule, wherein the reaction functions are as shown in the following function (1) and function (2).

Si_{(S)}+O_{2(g)}→SiO_{2(S)} function (1)

Si_{(S)}+H₂O_{(g)}→SiO_{2(S)}+2H_{2(g)} function (2)

The reaction mentioned above reacting with the oxygen is called dry oxidation method and another reaction mentioned above reacting with the water molecule is called wet oxidation method. In the present method for forming the oxide layer, usually, the gate oxide layer is using the dry oxidation method and the field oxide layer is using wet oxidation method. However, the oxide layer formed by the dry oxidation method has good electronic ability but a slow reaction rate, so the dry oxidation method is suitable for the gate oxide layer which is required better electronic ability. On the other hand, the rapidly wet oxidation method is usually using to form the field oxide layer with high thickness require.

For example, the oxidation process of the silicon wafer is comprising three steps. First, the oxygen molecule is transferred to the surface of the oxide layer. Then, the oxygen molecule is penetrating through the oxide layer and diffusing into the surface of the silicon wafer. Last, the oxygen molecule and the silicon atom are performing the oxidation reaction to form silicon dioxide. Wherein the three steps are continuously and simultaneously processing.

According the FIG. 1A to FIG. 1C further explains the conventional gate oxide layer utilizing the dry oxidation method mentioned above. First, as shown in the FIG. 1A, a semiconductor substrate 10 is provided. Then, referring to the FIG. 1B, performing the oxidation step is to grow a initial oxide layer 11 on the surface of the semiconductor substrate 10. Following, as shown in the FIG. 1C, the oxide layer 12 is formed till growing the require thickness.

However, in the initial period of the dry oxidation reaction, the thickness of the oxide layer is rapidly growing following a parabolic growing curve. For the manufacture of a thin gate oxide layer with a thickness about 100 to 200 angstroms the rapidly growing property have no special influence. But for preparing a very thin gate oxide layer with a thickness about 50 to 100 angstroms or thicker, the rapidly growing property will increase the difficult of thickness control of the gate oxide layer. If the properties of the gate oxide layer is enhanced required, such as uniform ability, dense ability, and etc., the process difficult is relatively increased.

Obviously, the main spirit of the present invention is to provide a method for forming super thin gate oxide layer which can reduce the oxidation rate of the oxide layer to overcome the disadvantage of too fast oxidation rate resulting in the difficult control of process parameters.

### SUMMARY OF THE INVENTION

The primary object of the invention is to provide a method for utilizing a re-oxidation step of a nitride layer to form a super thin nitride gate oxide layer to solve conventional disadvantages and limitation resulting from the well-known process for preparing the super thin gate oxide layer.

Another object of the invention is to provide a method for slowing the oxidation rate of the gate oxide layer to obtain a dense oxide layer in the manufacture process for preparing the super thin nitride gate oxide layer. The method utilizes a pre-formed very thin and high nitrogen contain oxide layer to grow a second oxide layer by rapidly thermal step to replace the conventional method for directly growing the super thin nitride gate oxide layer on the silicon substrate. The present method utilizes the re-oxidation step to reduce the growing rate of the oxide layer which can more easily control the thickness of the super thin oxide layer and obtain a more smooth interface performance between silicon and oxide layer at the same time which can reduce the density of the interface and improve the quality of the oxide layer.

A further object of the invention is to utilize the pre-grown high nitrogen-contain oxide layer to enhance the uniform ability of the oxide layer and to make the thickness control more accurately.

In order to achieve previous objects, a method for preparing a super thin nitride gate oxide layer of the present invention comprises following steps. First, a semiconductor substrate is provided and a very thin oxide layer is formed thereon, wherein the very thin oxide layer provided with a large quantity nitrogen element by a nitrogenization step or a nitrogen-penetrating treatment. Then, a rapidly thermal oxidation step is performed to grow required super thin gate oxide layer, wherein the different thickness of the required gate oxide layer is controlled by appropriate flow of oxygen, hydrogen, and nitrogen, the oxidation temperature, and reaction time.

Other aspects, features, and advantages of the present invention will become apparent as the invention becomes better understood by reading the following description in conjunction with the accompanying drawings.

### BRIEF DESCRIPTION OF THE DRAWINGS

The foregoing aspects and many of the accompanying advantages of this invention will become more readily appreciated as the sane becomes better understood by reference to the following detailed description, when taken in conjunction with the accompanying drawings, wherein:

FIG. 1A and FIG. 1C are schematic representations structures at various stages during the formulation of a super thin gate oxide layer, in accordance with prior techniques; and

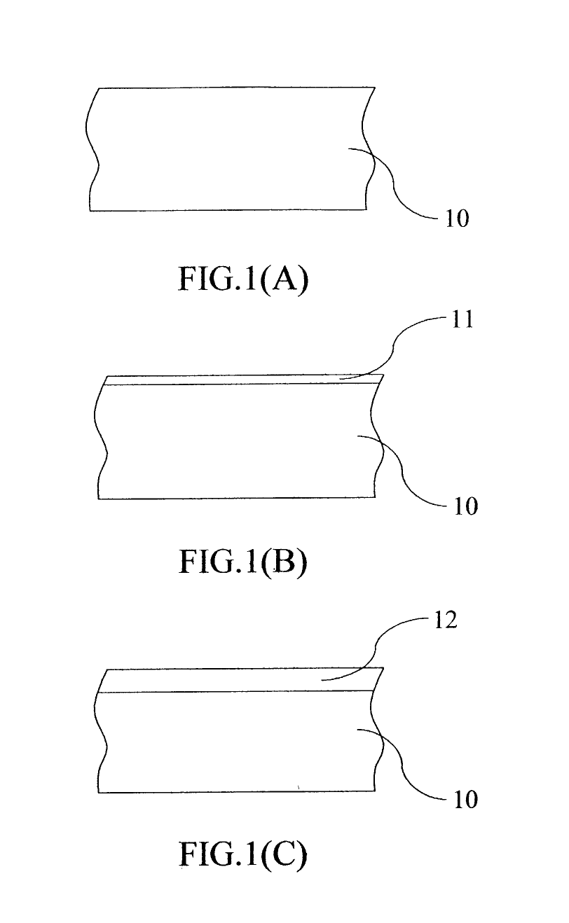

FIG. 2A and FIG. 2D are schematic representations structures at various stages during the formulation of a super thin gate oxide layer, in accordance with one preferred embodiment of the present invention.

### DESCRIPTION OF THE PREFERRED EMBODIMENT

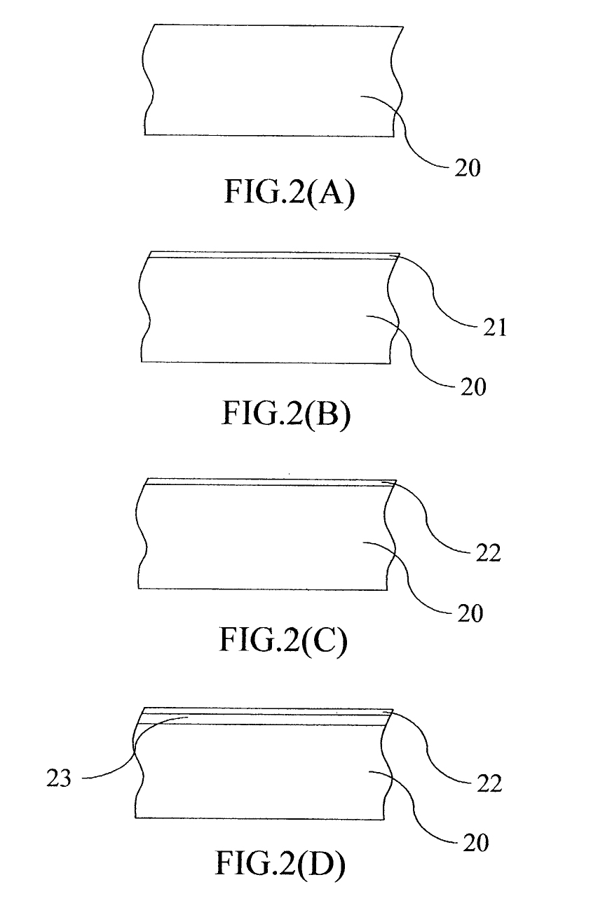

The present invention provides a preferred embodiments at various stages during the formulation of a super thin gate oxide layer in a cutaway view, such as shown in the FIG. 2A to FIG. 2D, to illustrate the key steps of the present invention.

Referring to the FIG. 2A, first, a semiconductor substrate 20 without any oxide layer thereon is provided, the substrate is usually made of silicon wafer and the substrate is to use as the bottom layer for forming other devices and to form the oxide layer thereon. For example, in the semiconductor process with silicon wafer as the substrate, it usually directly perform the dry oxidation reaction on surface of the silicon wafer to grow the gate oxide layer for the semiconductor devices.

Following, as shown in the FIG. 2B, a silicon dioxide layer 21 with a very thin thickness about 10 angstroms is uniformly grown on the semiconductor substrate 20 by using the dry oxidation process with a low oxygen flow and a lower temperature to stably grow the silicon oxide layer 21. In generally, in the thermal oxidation process, the silicon oxide layer 21 has a fast growing rate under the higher process temperature, higher oxygen flow, and higher operation pressure. Hence, to slow the temperature, pressure, and oxygen flow can obtain a very thin silicon oxide layer 21 which can also obtain by utilizing ozone reacting with the surface of the silicon wafer.

Next, immediately utilizing the nitridation method or nitrogen-penetrating treatment is to make the semiconductor substrate 20 or silicon oxide 21 having high nitrogen element contain to form an initial oxide layer 22 provided with high nitrogen element contain, referring to the FIG. 2C. The initial oxide layer 22 provided with high nitrogen element contain will enhance the complete bonding amount of the silicon oxide layer 21. The nitrogen element entering the silicon oxide layer 21 will bond with the un-complete bonding therein to make the structure of the initial oxide layer 22 more dense after the nitridation of the whole silicon oxide layer 21. It is also a key point in the following processes.

Then, referring to the FIG. 2D, after finishing the formation of the initial oxide layer 22 with high nitrogen element contain, the whole structure is exposed in nitrogen surrounding without atmosphere. Then, the second step rapidly thermal oxidation process is directly performed. Now, oxygen (or oxygen and nitrogen) is filling in and simultaneously rising the temperature to perform the oxidation reaction. Wherein the oxygen (or oxygen and nitrogen) is diffusing into the initial oxide layer 22, which is provided with high nitrogen element contain, from the gas phase region and then diffusing into the surface of the semiconductor substrate 20 to contact with silicon and oxidize with silicon to form a gate oxide layer 23 within the semiconductor substrate 20 and underlying the initial oxide layer 22. Owing to the initial oxide layer 22 has a better dense ability, it slows down the diffuse rate of the oxygen atom to diffuse and through the initial oxide layer 22 so as can reduce the growing rate of the underlying oxide layer 23. Hence, the present invention can easily enhance the uniform and dense ability of the oxide layer and to make the thickness control more accurately when using thermal oxidation process to form the super thin gate oxide layer 23.

Last, the present invention can obtain the gate oxide layer 23 with required thickness, uniform ability, and dense ability to solve the disadvantage of the difficult thickness control resulting from the too fast oxidation rate of conventional process for preparing the super thin gate oxide layer.

Hence, the present invention provides a method for utilizing a re-oxidation step of a nitride layer to form a super thin nitride gate oxide layer which can not only obtain a super thin gate oxide layer with better uniform ability and required thickness but also can solve conventional disadvantages and limitation resulting from the well-known process for preparing the super thin gate oxide layer. Furthermore, the present method utilizes the re-oxidation step to reduce the growing rate of the oxide layer which can more easily control the thickness of the super thin oxide layer and obtain a more smooth interface performance between silicon and oxide layer at the same time which can reduce the density of the interface and improve the quality of the oxide layer.

Of course, it is to be understood that the invention described herein is not intended to be exhaustive or to limit the invention to he precise from disclosed. The description was selected to best explain the principles of the invention and practical application of these principles to enable others skilled in the art to best utilize the invention in various embodiments and modifications as are suited to the particular use contemplated. It is intended that the scope of the invention not to be limited by the specification, but be defined by the claim set forth below.

What is claimed is:

1. A method for utilizing a re-oxidation step of a nitride layer to form a super thin nitride gate oxide layer, said method comprising:
providing a semiconductor substrate;
forming an initial oxide layer on said semiconductor substrate, wherein said initial oxide layer is provided with a high nitrogen contain and a very thin thickness; and
utilizing a rapidly thermal re-oxidation step to form an oxide layer within said semiconductor substrate and underlying said initial oxide layer to form a uniform and thickness-controlled accurately gate oxide layer.

2. The method according to claim 1, wherein said semiconductor substrate is a silicon wafer.

3. The method according to claim 1, wherein a thickness of said initial oxide layer is smaller than 10 angstroms.

4. The method according to claim 1, wherein said initial oxide layer is a silicon oxide layer provided with a high nitrogen element contain.

5. The method according to claim 1, wherein said initial oxide layer is a silicon nitride oxide layer provided with a high nitrogen element contain.

6. The method according to claim 1, wherein said initial oxide layer is a silicon nitride layer provided with a high nitrogen element contain.

7. The method according to claim 1, wherein said initial oxide layer is utilizing a nitrogen-penetrating treatment to provide with a great quantity nitrogen element contain to form said initial oxide layer provided with a high nitrogen contain.

8. The method according to claim 1, wherein a thickness of said gate oxide layer is smaller than 100 angstroms.

9. The method according to claim 1, wherein said oxide layer is formed by furnace to perform a oxidation reaction by filling in oxygen to rising the temperature therein.

10. The method according to claim 1, wherein said oxide layer is formed by furnace to perform a oxidation reaction by filling in oxygen and hydrogen to rising the temperature therein.

11. The method according to claim 1, wherein said oxide layer is formed by furnace to perform a oxidation reaction by filling in oxygen, hydrogen, and nitrogen with a different proportion to rising the temperature therein.
